(19) United States
(12) Patent Application Publication
(10) Pub. No.: US 2026/0280235 A1
(43) Pub. Date: Sep. 17, 2026

(54) LASER EMITTER ASSEMBLY AND METHOD FOR PROVIDING AN OUTPUT LASER BEAM AT AN OUTPUT OF A LASER EMITTER ASSEMBLY

(71) Applicant: TRUMPF Laser SE, Schramberg (DE)

(72) Inventors: Stephan Strohmaier, Berlin (DE); Thomas Rataj, Berlin (DE); Christoph Tillkorn, Villingendorf (DE)

(21) Appl. No.: 19/678,217

(22) Filed: May 15, 2026

Related U.S. Application Data
(63) Continuation of application No. PCT/EP2024/083684, filed on Nov. 27, 2024.

(30) Foreign Application Priority Data
Dec. 1, 2023 (DE) 10 2023 133 710.6

(51) Int. Cl. H01S 5/40

(52) U.S. Cl. CPC H01S 5/4012; H01S 5/4031

(57) ABSTRACT

A laser emitter assembly for providing an output laser beam at an output of the laser emitter assembly is provided. The laser emitter assembly includes a base, and a plurality of laser emitter devices attached to the base. Each laser emitter device includes an emitter. Each respective laser emitter device is configured to generate a respective laser beam and emit the respective laser beam in a respective emission direction. Each respective emission direction extends obliquely with respect to the base and/or with respect to a longitudinal axis of the emitter of the respective laser emitter device. The output laser beam is formed from the laser beams of the plurality of laser emitter devices.

### CROSS REFERENCE TO RELATED APPLICATIONS

This application is a continuation of International Application No. PCT/EP2024/083684 (WO 2025/114317 A1), filed on Nov. 27, 2024, and claims benefit to German Patent Application No. DE 10 2023 133 710.6, filed on Dec. 1, 2023. The aforementioned applications are hereby incorporated by reference herein.

### FIELD

Embodiments of the present invention relate to a laser emitter assembly and a method for providing an output laser beam at an output of a laser emitter assembly.

### BACKGROUND

A laser emitter assembly can provide an output laser beam, for example for optical pumping of a laser-active medium of a solid-state laser. The solid-state laser can be designed, for example, as a disk laser or a fiber laser. Consequently, the output laser beam provided by the laser emitter assembly can be suitable for optical pumping, for example of solid-state lasers.

In addition to optical pumping, the output laser beam of the laser emitter assembly may be used for further applications when the output laser beam is provided with a certain power, for example for processing workpieces or in medical technology. In such applications, the output laser beam can not only function as an optical pump source, but can at least be designed as an unamplified processing/treatment laser beam.

### SUMMARY

Embodiments of the present invention provide a laser emitter assembly for providing an output laser beam at an output of the laser emitter assembly. The laser emitter assembly includes a base, and a plurality of laser emitter devices attached to the base. Each laser emitter device includes an emitter. Each respective laser emitter device is configured to generate a respective laser beam and emit the respective laser beam in a respective emission direction. Each respective emission direction extends obliquely with respect to the base and/or with respect to a longitudinal axis of the emitter of the respective laser emitter device. The output laser beam is formed from the laser beams of the plurality of laser emitter devices.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic top view of a laser emitter assembly according to some embodiments;

FIG. 2 shows a schematic oblique view of the laser emitter assembly of FIG. 1 according to some embodiments;

FIG. 3 shows a further schematic oblique view of the laser emitter assembly of FIG. 1 according to some embodiments;

FIG. 4 shows a schematic oblique view of a laser emitter device of the laser emitter assembly of FIG. 1 without a fast-axis collimator lens according to some embodiments;

FIG. 5 shows a schematic side view of the laser emitter device of FIG. 4 with fast-axis collimator lens according to some embodiments;

FIG. 6 shows a schematic representation of a deflecting mirror of the laser emitter assembly of FIG. 1 according to some embodiments;

FIG. 7 shows a schematic oblique view of the deflecting mirror of FIG. 6 according to some embodiments;

FIG. 8 shows a schematic representation of an optical device of the laser emitter assembly of FIG. 1 according to some embodiments;

FIG. 9 shows a schematic representation of a cross-section of an output laser beam provided by the laser emitter assembly of FIG. 1 according to some embodiments;

FIG. 10 shows a schematic representation of a laser emitter assembly according to some embodiments;

FIG. 11 shows a schematic top view of the laser emitter assembly of FIG. 10 according to some embodiments;

FIG. 12 shows a schematic top view of a laser emitter assembly according to some embodiments;

FIG. 13 shows a schematic oblique view of the laser emitter assembly of FIG. 12 according to some embodiments;

FIG. 14 shows a further schematic oblique view of the laser emitter assembly of FIG. 12 according to some embodiments;

FIG. 15 shows a schematic representation of a cutout of a cross-section of an output laser beam provided by the laser emitter assembly of FIG. 12 according to some embodiments;

FIG. 16 shows a schematic top view of a laser emitter assembly according to some embodiments;

FIG. 17 shows a schematic oblique view of the laser emitter assembly of FIG. 16 according to some embodiments;

FIG. 18 shows a further schematic oblique view of the laser emitter assembly of FIG. 16 according to some embodiments;

FIG. 19 shows a schematic oblique view of an area XIX in FIG. 17 according to some embodiments;

FIG. 20 shows a further schematic oblique view of the area XIX in FIG. 17 according to some embodiments; and

FIG. 21 shows a schematic representation of a coupling element of the laser emitter assembly of FIG. 16 according to some embodiments.

### DETAILED DESCRIPTION

Embodiments of the present invention provide a laser emitter assembly which has improved properties, in particular is cost-effective to manufacture and/or is suitable for providing a high-power output laser beam. Embodiments of the present invention also provide a method for supplying an output laser beam at an output of a laser emitter assembly, which has improved properties, in particular with which the output laser beam can be supplied at the output with high power.

A laser emitter assembly according to embodiments of the invention is configured to provide an output laser beam at an output of the laser emitter assembly. The laser emitter assembly comprises a base and a plurality of, for example 8 to 30, in particular 10 to 25, laser emitter devices. The plurality of laser emitter devices are attached to the base. The plurality of laser emitter devices have at least one emitter each. Each laser emitter device is designed to generate a laser beam and emit it in an emission direction. Each emission direction extends obliquely with respect to the base and/or with respect to a longitudinal axis of the emitter. The output laser beam is formed from the laser beams of the laser emitter devices.

Advantageously, due to the oblique extensions of the emission directions, a particularly clear and simple design of the laser emitter assembly can be achieved. Furthermore, due to the oblique extensions of the emission directions, the number of components required for providing the output laser beam at the output can be reduced, so that very few components are needed to realize the laser emitter assembly, making the laser emitter assembly particularly cost-effective. Considering that every component over which a laser beam is guided can reduce the power of the laser beam, the power losses of the laser emitter assembly can be advantageously kept low due to the small number of components required, which is why the laser emitter assembly is particularly suitable for providing a high-power output laser beam.

Each emission direction that extends obliquely with respect to the base and/or with respect to a longitudinal axis of the emitter can be described as an emission direction that extends obliquely, in particular is obliquely oriented, to the base and/or longitudinal axis of the emitter.

An emission direction that extends obliquely to the base and/or the longitudinal axis of the emitter means that the emission direction is not parallel to the base and/or the longitudinal axis of the emitter.

Due to the obliquely extending emission direction, the distance between each laser beam and the base may depend on the propagation path travelled by the laser beam. In other words, the distance can change depending on the propagation path traveled by the laser beam. For example, the distance can increase depending on the propagation path traveled by the laser beam. Preferably, the distance can increase proportionally to the propagation path traveled by the laser beam. The propagation path traveled by the laser beam can be the propagation path traveled from the laser emitter device that emits the laser beam. The output laser beam can be formed from the laser beams depending on the propagation path traveled and/or on the distance between the laser beam and the base.

Distance can be understood as a height, in particular a height between a laser beam and the base. The distance can be determined perpendicularly, in particular parallel to a perpendicular on the base.

The emission directions can be oriented parallel to one another.

Each emission direction can be directed away from the base. In particular, at least one directional component of the emission direction can be directed away from the base.

Each laser beam can propagate along a propagation direction. In particular, any propagation direction can be the same as the emission direction.

The base can be cuboid in shape. The height of the base can be less than the width and/or length of the base.

The base can be designed as a cooled plate for cooling the laser emitter devices. The base may be designed to allow a cooling medium, such as cooling water, to flow through it for the purpose of cooling the laser emitter devices. However, it is also possible to cool the base directly or indirectly via a separate cooling plate. In the case of indirect cooling, a heat transfer layer can be positioned between the base and the cooling plate, which has a material with a comparatively high thermal conductivity coefficient, for example a carbon material, in particular graphite. The cooling plate may be designed to be flowed through or flowed over for the purpose of cooling the laser emitter devices. The heat transfer layer can have a thickness of 50 μm to 1000 μm, in particular 100 μm to 500 μm, preferably 150 μm to 250 μm and particularly preferably 200 μm.

The base can be designed to be attached to an object, for example, to an optical table. The base can have a number of elements, for example in the form of through-holes and/or threads, for attaching the base to the object. The base can be made of a metal material, in particular copper (Cu).

The laser emitter devices can be connected to the base by a form-fit and/or material-fit connection. For example, the laser emitter devices can be attached to the base by means of an adhesive bond, a soldered connection or a welded connection. The adhesive bond can be created using a UV adhesive. UV adhesive can be an adhesive that can be hardened by irradiation with ultraviolet light. Additionally or alternatively, it should be understood that the adhesive bond can be made using an adhesive that has a thermal conductivity of over 0.5 watts/(meter*kelvin).

The laser emitter devices can be thermally connected to the base such that the connection between each laser emitter device and the base has a thermal conductivity of at least 0.5 watts/(meter*kelvin). In particular, the thermal conductivity of the connection between each laser emitter device and the base can range from 0.5 watts/(meter*kelvin) to 150 watts/(meter*kelvin).

The laser emitter devices can be attached to the base at a distance from one another.

Each laser beam can have a fast-axis direction and a slow-axis direction. The laser emitter devices can be positioned on the base such that the slow-axis directions of the laser beams extend, and in particular are oriented, parallel to the base.

The fast-axis direction and the slow-axis direction can be orthogonal to one another. The laser beam emerging from the emitter can define the fast-axis direction and the slow-axis direction. The laser beam that exits from the emitter can propagate in the fast-axis direction with a larger divergence angle than in the slow-axis direction. In other words, when the laser beam exits the emitter, the laser beam can propagate along its propagation direction, with the diameter of the laser beam in the fast-axis direction increasing more strongly than a diameter of the laser beam in the slow-axis direction up to a fast-axis collimator lens of the laser emitter device.

Each laser beam can have a beam quality factor M² in the fast-axis direction in a range of 1 to 2 and a beam quality factor M² in the slow-axis direction in a range of 14 to 50. The beam quality factors M² of the laser beams in the fast-axis direction can be the same, in particular in their magnitudes. Additionally or alternatively, the beam quality factors M² of the laser beams in the slow-axis direction, in particular in their magnitudes, can be equal.

The term emitter can be understood as a laser diode bar. Each emitter can contain a semiconductor laser material. Each laser emitter device can have a single emitter. Each laser emitter device can have a “chip on submount” design.

Each emitter can extend along the longitudinal axis. Each longitudinal axis of the emitter can be oriented parallel to the base. The longitudinal axes of the emitters can be oriented parallel to one another.

The emitter can be positioned, in particular attached, to a mounting plate of the laser emitter device. The mounting plate can be positioned on the emitter, forming a flat interface that is orthogonal to the fast-axis direction. The flat interface can be oriented parallel to the base. The mounting plate can be attached to the base.

The laser emitter devices can be identical in construction. In particular, the laser emitter devices can be designed identically.

Each laser emitter device can have a laser emitter output from which the laser beam exits. Each laser emitter output can be spaced at a distance from the base. The distances of the laser emitter outputs from the base can be the same.

The laser emitter devices can be attached to the base to form at least one laser emitter row. For example, the laser emitter devices can be attached to the base to form a first laser emitter row and a second laser emitter row. The first laser emitter row and the second laser emitter row can be oriented parallel to one another. The first laser emitter row and the second laser emitter row can be positioned offset to one another.

The output laser beam can be formed by polarization coupling and/or by wavelength coupling of the laser beams of the laser emitter devices of the first laser emitter row with the laser beams of the laser emitter devices of the second laser emitter row. The output laser beam can be formed such that at least one laser beam of the second laser emitter row is positioned between two adjacent laser beams of the first laser emitter row. The output laser beam can also be formed such that the laser beams of the first laser emitter row and the laser beams of the second laser emitter row are positioned alternately at the output. The output laser beam can also be formed by laser beams from the first and second laser emitter rows that are superimposed on one another.

The output laser beam can be a laser beam group formed from the laser beams. Preferably, the output laser beam can consist of the laser beams. The output laser beam can propagate in one propagation direction. The propagation direction of the output laser beam can be oriented parallel to the base.

The output laser beam can be designed to be coupled into a waveguide for guiding the output laser beam. The waveguide can be, for example, an optical fiber or a fiber optic cable. The output laser beam can be designed to be coupled into the waveguide if an end face of the waveguide is positioned at the output. It is also conceivable that the laser emitter assembly can have the waveguide and the output is formed by the end face of the waveguide. Alternatively, the output can be formed through an opening in a housing of the laser emitter assembly.

The output laser beam can be formed by directing the laser beams towards the output, in particular by means of optical components of the laser emitter assembly. The optical components of the laser emitter assembly can be attached to the base.

The output laser beam can be formed by arranging the laser beams relative to one another, in particular by means of optical components of the laser emitter assembly. Forming the output laser beam can involve arranging the laser beams one above the other in the fast-axis direction. In a cross-section of the output laser beam, the laser beams can be positioned one above the other in the fast-axis direction, for example at equal distances from each other. In the cross-section of the output laser beam, the laser beams can at least partially superimpose, in particular overlap.

The laser beams can be positioned in the cross-section of the output laser beam to form a laser beam row. The laser beam row can be oriented perpendicular to the base.

The laser beams can be positioned in the cross-section of the output laser beam such that the propagation directions of the laser beams are oriented parallel to one another. Additionally, the propagation directions of the laser beams in the cross-section of the output laser beam can be offset from each other.

The output laser beam can exit the output with a predetermined beam diameter and a predetermined divergence, pass through the output and/or be guided through the output. In other words, the output can be provided for the exit of the output laser beam from the laser emitter assembly.

At the output, the output laser beam can have a beam diameter in the range of, for example, 100 μm (micrometers) to 1500 μm, in particular 200 μm to 500 μm. At the output, the output laser beam can have a divergence angle in the range of, for example, 5° to 40°, in particular 10° to 25°.

The laser emitter assembly may include a focusing device, for example in the form of a focusing lens, for focusing the output laser beam onto the output. The focusing lens can be made of quartz glass. The focusing lens may have an anti-reflective coating for a wavelength of the laser beams from the laser emitter devices. The anti-reflective coating may be suitable for reducing the reflectance of laser beams at interfaces of the focusing lens. The focusing lens can be radially symmetrical. However, it can also have two cylindrical lenses perpendicular to one another and possibly cemented or glued together, and in particular be formed by these.

The output can be located in a focal plane of the focusing device. The focal plane can be located in the propagation directions of the laser beams after the focusing device. The output may be limited by a maximum focus diameter of the focusing device in the focal plane. The maximum focus diameter may depend on the apertures of the emitters.

The laser emitter assembly can have a waveguide receptacle for a waveguide. The waveguide receptacle can be positioned at an opening in the housing of the laser emitter assembly. The housing may have an interior in which the laser emitter devices are positioned. A waveguide can be accommodated by the waveguide receptacle. The waveguide can be accommodated by the waveguide receptacle such that an end face of the waveguide is positioned at the output. The output laser beam can be formed from the laser beams and focused onto the end face of the waveguide by means of the focusing device. By focusing the output laser beam onto the end face of the waveguide, the output laser beam can be coupled into the waveguide. The end face can have an anti-reflective coating that is particularly low in reflectance for a specific wavelength of the laser beams.

Alternatively, the output can be an opening in a housing of the laser emitter assembly. The housing may have an interior in which the laser emitter devices are positioned. The output laser beam can be formed from the laser beams and focused onto the opening by means of the focusing device. The output laser beam can be guided through the opening by means of the focusing device. However, the output laser beam can also pass through the opening and only then enter the focusing device if the focusing device is positioned outside the housing of the laser emitter assembly. A sealing element that transmits the wavelength of the laser beams, for example in the form of a transparent protective glass, can be positioned in or adjacent to the opening, which largely prevents unwanted foreign particles from entering the interior of the housing.

A further aspect of the invention is that the obliquely extending emission directions enable a particularly dense and/or compact assembly of the laser beams next to one another for the purpose of forming the output laser beam, whereby the laser emitter assembly can provide an output laser beam formed from a greater number of laser beams. Therefore, the laser emitter assembly can provide an output laser beam with particularly high power.

In a further development of the laser emitter assembly, the base has a flat surface portion. The laser emitter devices are positioned on the flat surface portion. Each emission direction extends obliquely relative to the flat surface portion. Advantageously, producing the flat surface portion can be particularly simple and cost-effective. Any emission direction that extends obliquely to the flat surface portion, in particular that is obliquely oriented, can be understood to mean that the emission direction is not parallel to the flat surface portion. The course of the base and the course of the flat surface portion can be the same.

The flat surface portion can be a contiguous surface portion. The flat surface portion can be an uninterrupted surface portion. The flat surface portion can be positioned in a single plane of the base. Alternatively, the flat surface portion can define a single plane of the base. The flat surface portion can form a surface of the base. The surface formed by the flat surface portion can be positioned in one, in particular a single, plane. The base can have a single flat surface portion for arranging the laser emitter devices. In other words, the laser emitter devices can be positioned on a single flat surface portion.

The laser emitter assembly can include a plurality of deflecting mirrors. Each deflecting mirror can be assigned to a laser emitter device. Each deflecting mirror can be designed to deflect the propagation direction of the laser beam of the laser emitter device associated with the deflecting mirror by 80° to 100°, in particular 85° to 95° or 88° to 92°, preferably 90°. The deflecting mirrors can be attached to the base. The deflecting mirrors can be positioned on the flat surface portion. The deflecting mirrors can be of identical construction.

Each deflecting mirror can have a straight edge that extends obliquely relative to the flat surface portion. In every deflecting mirror, the straight edge extending obliquely can define a side surface of the deflecting mirror that faces away from the base.

At least one deflecting mirror can be positioned to deflect the laser beam of the laser emitter device associated with the deflecting mirror such that the deflected laser beam passes along the straight edge of another deflecting mirror extending obliquely.

In a further development of the laser emitter assembly, each emission direction and the base, in particular the flat surface portion between them, define a radiation angle. Each of the radiation angles between the emission directions and the base, in particular the flat surface portion, is not equal to 0°. Additionally or alternatively, each emission direction and the longitudinal axis of the emitter define a radiation angle between them. Each of the radiation angles between the emission directions and the longitudinal axes of the emitters is not equal to 0°. The radiation angle between the emission direction and the base and the radiation angle between the emission direction and the longitudinal axis of the emitter can be the same.

In a further development of the laser emitter assembly, each radiation angle between the emission direction and the base, in particular the flat surface portion, and/or each radiation angle between the emission direction and the longitudinal axis of the emitter is 0.5° to 20°, in particular 0.5° to 10°, 1° to 5° or 2° to 4°. Advantageously, the laser emitter assembly can be built in a particularly compact manner with such a radiation angle.

In a further development of the laser emitter assembly, each laser emitter device has a fast-axis collimator lens for collimating the laser beam in a fast-axis direction. In every laser emitter device, the fast-axis collimator lens is positioned relative to the emitter such that the emission direction extends obliquely with respect to the base, in particular to the flat surface portion, and/or with respect to a longitudinal axis of the emitter.

The oblique extensions of the emission directions can be formed by positioning the fast-axis collimator lens relative to the emitters.

The fast-axis collimator lens of each laser emitter device can be positioned relative to the emitter, in particular for the purpose of emitting the laser beam in the emission direction, such that the fast-axis collimator lens changes the propagation direction of the laser beam.

The fast-axis collimator lens can be a cylindrical lens, in particular an aspheric cylindrical lens. The fast-axis collimator lens can be made of quartz glass. The fast-axis collimator lens can have an anti-reflective coating for a wavelength of the laser beam of the laser emitter device. The anti-reflective coating may be suitable for reducing the reflectance of the laser beam at interfaces of the fast-axis collimator lens. The fast-axis collimator lens can be attached to the mounting plate, in particular by means of an adhesive bond. The adhesive bond can be created, for example, using a UV adhesive.

In a further development of the laser emitter assembly, the longitudinal axis of the emitter and an optical plane of the fast-axis collimator lens have different orientations in each laser emitter device, in particular for the purpose of emitting the laser beam in the emission direction.

The optical plane can be oriented perpendicular to a lens plane of the fast-axis collimator lens. The optical plane can contain a center point of the fast-axis collimator lens. The optical plane of the fast-axis collimator lens can be a plane of symmetry of the fast-axis collimator lens. The optical plane can be a plane of mirror symmetry of the fast-axis collimator lens. In particular, the optical plane can be the plane of symmetry of the fast-axis collimator lens, which is oriented perpendicular to the lens plane of the fast-axis collimator lens. A laser beam passing through the fast-axis collimator lens can be refracted by the fast-axis collimator lens in the direction of the optical plane.

The longitudinal axis of the emitter cannot lie within the optical plane. The longitudinal axis of the emitter can intersect the optical plane at a single point or be oriented parallel and offset to the optical plane.

In a further development of the laser emitter assembly, the fast-axis collimator lens of each laser emitter device is arranged relative to the emitter, in particular relative to the longitudinal axis of the emitter, with a transverse offset in the fast-axis direction, in particular for emitting the laser beam in the emission direction. The transverse offset allows the laser beam to be emitted in the obliquely extending emission direction. The transverse offset allows the center point of the fast-axis collimator lens to be spaced away from the longitudinal axis of the emitter.

In a further development of the laser emitter assembly, the fast-axis collimator lens of each laser emitter device is tilted by a tilt angle relative to the longitudinal axis of the emitter. By tilting the fast-axis collimator lens, the laser beam can be emitted in the obliquely extending emission direction. In any laser emitter device, the optical plane of the fast-axis collimator lens and the longitudinal axis of the emitter can define the tilt angle between them. The tilt angle can be not equal to 0°.

In a further development of the laser emitter assembly, the tilt angle is 0.5° to 20°, in particular 0.5° to 10°, 1° to 5° or 2° to 4°. Advantageously, such tilt angles are particularly suitable for emitting laser beams in the obliquely extending emission direction.

In a further development of the laser emitter assembly, each longitudinal axis of the emitters extends obliquely relative to the base. In particular, each longitudinal axis of the emitter can extend obliquely relative to the flat surface portion of the base. For example, each laser emitter assembly can have a wedge element positioned between the mounting plate and the base, wherein the wedge element forms the oblique extension of the longitudinal axis of the emitters. Alternatively, the mounting plate of the laser emitter assembly can have a surface that extends obliquely with respect to the longitudinal axis of the emitter, wherein the oblique extension of the longitudinal axis of the emitter is formed by the obliquely extending surface.

In a further development of the laser emitter assembly, the laser emitter assembly has a housing. The base forms a wall section of the housing. The housing may have an interior in which the laser emitter devices are positioned. The base can partially form a side wall of the housing.

In a further development of the laser emitter assembly, each laser beam travels a propagation path from the laser emitter device generating the laser beam to the output of the laser emitter assembly. The output laser beam is formed from the laser beams of the laser emitter devices depending on the propagation paths of the laser beams from the laser emitter devices to the output. This makes it particularly easy to generate the output laser beam.

The laser beams can have propagation paths with lengths different from each other.

The position of a laser beam in the cross-section of the output laser beam, in particular at the output, can depend on the length of its propagation path. In other words, the length of the propagation path of a laser beam can determine its position in the cross-section of the output laser beam, in particular at the output.

In other words, the assembly of the laser beams, in particular relative to one another, in the cross-section of the output laser beam, in particular at the output, can depend on the lengths of the propagation paths.

In a further development of the laser emitter assembly, the laser emitter assembly includes an optical device that is arranged between the output and the plurality of laser emitter devices. The laser beams pass through the optical device for the purpose of changing the propagation directions of the laser beams.

The optical device may be designed such that the propagation directions of the laser beams are oriented parallel to the base, in particular to the flat surface portion, and/or to the longitudinal axes of the emitters.

In the propagation direction following the optical device, the distance between the laser beam and the base, in particular the flat surface portion, can remain constant from the optical device onwards. In other words, once a laser beam has passed through the optical device, the distance between the laser beam and the base, in particular the flat surface portion, can remain constant from the optical device onwards.

Each laser beam can strike the optical device at an angle of incidence that is not equal to 0° for the purpose of changing the propagation direction. The angle of incidence can be equal to the radiation angle. The optical device can be wedge-shaped and/or designed as an optical wedge. The optical device can be designed to change the propagation directions of the laser beams by means of refraction of the laser beams, for example in the direction of the base or in the direction of the flat surface portion of the base. The optical device can be designed to change the propagation directions of the laser beams, in particular only in the fast-axis direction.

The laser emitter assembly can comprise a polarization coupling device and/or a wavelength coupling device. The output laser beam can be formed by polarization coupling of the laser beams using the polarization coupling device and/or by wavelength coupling using the wavelength coupling device of the laser beams. The optical device can include the polarization coupling device and/or the wavelength coupling device. The optical device can be materially bonded to a polarizer of the polarization coupling device and/or a mirror of the wavelength coupling device to form a coupling element.

In a further development of the laser emitter assembly, the laser emitter devices can be positioned on the flat surface portion to form a first laser emitter row and a second laser emitter row. Each radiation angle between the emission direction of a laser emitter device of the first laser emitter row and the flat surface portion can be smaller in magnitude than the magnitude of the radiation angle between the emission direction of a laser emitter device of the second laser emitter row and the flat surface portion. Each deflecting mirror can be assigned to a laser emitter device. The deflecting mirrors assigned to the laser emitter devices of the second laser emitter row can each be oriented orthogonally to the base, in particular the flat surface portion. The deflecting mirrors assigned to the laser emitter devices of the first laser emitter row can each be oriented with a tilt angle to the base, in particular the flat surface portion. The deflecting mirrors assigned to the laser emitter devices of the first laser emitter row can each be oriented with a tilt angle to the base, in particular the flat surface portion, such that the laser beams of the laser emitter devices of the first laser emitter row and the laser beams of the laser emitter devices of the second laser emitter row are oriented parallel to one another after being deflected by the deflecting mirrors.

A method according to embodiments of the invention is configured to provide an output laser beam at an output of a laser emitter assembly. The method includes the steps: Attaching of a plurality of, for example 10 to 25, laser emitter devices of the laser emitter assembly to a base of the laser emitter assembly, wherein each laser emitter assembly has at least one emitter; Generating of laser beams by means of the laser emitter devices and emitting the laser beams from the laser emitter devices in each of the following emission directions, which extend obliquely with respect to the base and/or with respect to a longitudinal axis of the emitter; and formation of the output laser beam from the laser beams of the laser emitter devices. The method may be designed to operate the above-described laser emitter assembly.

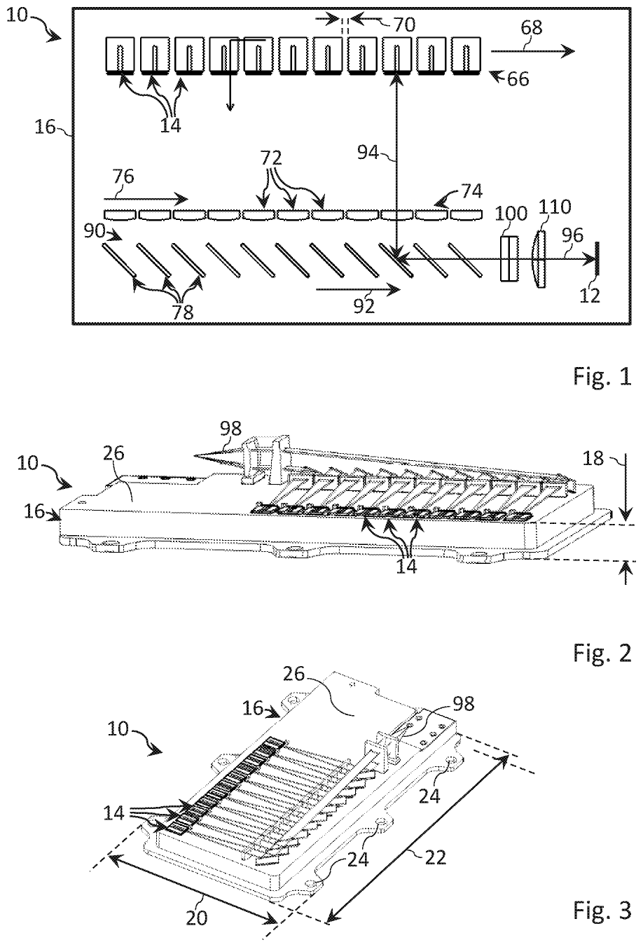

FIGS. 1 to 3 show a laser emitter assembly 10. The laser emitter assembly 10 is designed to provide an output laser beam at an output 12 of the laser emitter assembly 10.

The laser emitter assembly 10 has a plurality of identical laser emitter devices 14 and a base 16.

The base 16 is cuboid in shape. A height 18 of the base is smaller than a width 20 and a length 22 of the base 16.

The base 16 is designed to be attached to an object, for example an optical table and/or a housing part of an enclosing housing for the laser emitter assembly 10. The base 16 has a number of through-holes 24 for attaching the base 16 to the object. For example, the base 16 can be attached to the object by means of a screw connection, the screws of the screw connection being guided through the through-holes 24. In the illustrated exemplary embodiment, the base 16 has six through-holes 24. However, a base with a lower or higher number of through-holes 24 is also conceivable.

The base 16 has a flat surface portion 26. The flat surface portion 26 is a continuous and uninterrupted surface portion. The flat surface portion 26 forms a single plane of the base 16. The flat surface portion 26 is a surface of the base 16.

The laser emitter devices 14 are positioned on the flat surface portion 26 and attached to the base 16. In the illustrated exemplary embodiment, the laser emitter assembly 10 has a total of 11 laser emitter devices 14. However, a laser emitter assembly with a lower or higher number of laser emitter devices is also conceivable. In exemplary embodiments not specifically shown, for example, only eight laser emitter devices 14 or up to 32 laser emitter devices 14 are present.

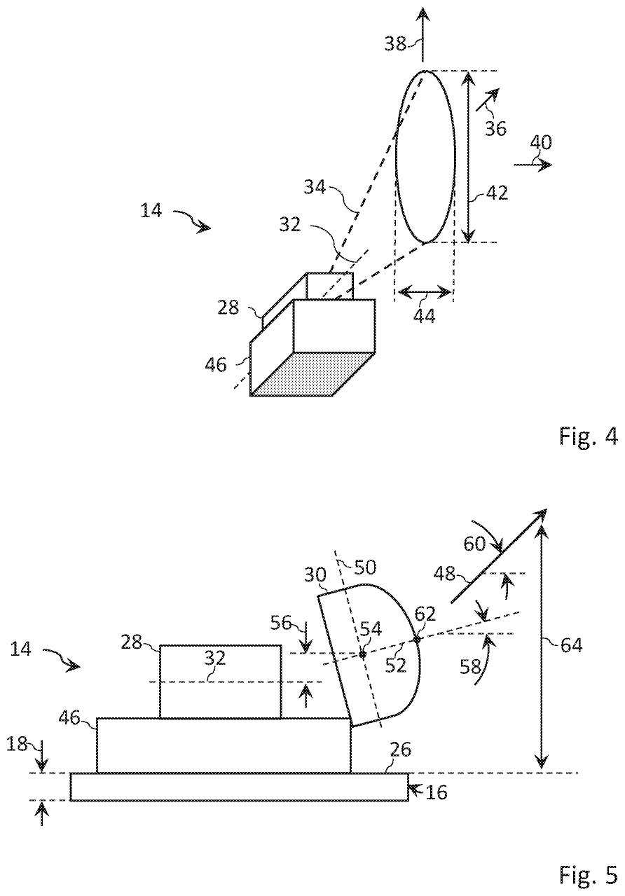

Each laser emitter device 14 has an emitter 28 made of a semiconductor laser material and a fast-axis collimator lens 30. FIG. 4 shows a single laser emitter device 14 of the laser emitter assembly 10 without the fast-axis collimator lens 30.

FIG. 4 shows that the laser emitter device 14 has a single emitter 28. The emitter 28 extends along a longitudinal axis 32. The emitter 28 is designed to generate a laser beam 34. The laser emitter device 14 is thus designed to generate the laser beam 34. The longitudinal axis 32 of the emitter 28 is oriented parallel to the flat surface portion 26.

In the illustrated exemplary embodiment of FIG. 4, the emitter 28 emits the laser beam 34. The laser beam 34 propagates along its propagation direction 36. The propagation direction 36 and the longitudinal axis 32 of the emitter 28 are oriented parallel to one another. In particular, the propagation direction 36 and the longitudinal axis 32 of the emitter 28 can have the same course.

The laser beam 34 that exits the emitter 28 defines a fast-axis direction 38 and a slow-axis direction 40, which are orthogonal to one another. When the laser beam 34 exits the emitter 28, the laser beam 34 propagates along its propagation direction 36, with a diameter 42 of the laser beam 34 increasing more rapidly in the fast-axis direction 38 than a diameter 44 of the laser beam 34 in the slow-axis direction 40. Consequently, the laser beam 34 has an elliptical cross-section after exiting the emitter 28.

The emitter 28 is positioned on and held in place by a mounting plate 46 of the laser emitter device 14. The mounting plate 46 contacts the emitter 28 in a flat interface that is orthogonal to the fast-axis direction 38. The flat interface is oriented parallel to the flat surface portion 26.

FIG. 5 shows the laser emitter device 14 of FIG. 4 with the fast-axis collimator lens 30. The laser emitter device 14 is attached to the base 16. The laser emitter device 14 is attached to the base 16 by means of a connection between the base 16 and the mounting plate 46. In this case, the connection is, for example, a soldered connection.

The soldered connection has a thermal conductivity of at least 35 watts/(meter*kelvin). Heat generated in the emitter 28 during the generation of the laser beam 34 is dissipated from the emitter 28 by means of the mounting plate 46 and the base 16.

The fast-axis collimator lens 30 is set up to collimate the laser beam 34 in the fast-axis direction 38. In other words, the laser beam 34 emitted by the laser emitter device 14 is collimated in the fast-axis direction 38.

The fast-axis collimator lens 30 is an aspherical cylindrical lens made of quartz glass, in this case made of quartz glass with a particularly high refractive index. The fast-axis collimator lens 30 has an anti-reflective coating which reduces the proportion of reflected light to a relative minimum for a wavelength of the laser beam 34. The anti-reflective coating reduces the reflectance of the laser beam 34 at the interfaces of the fast-axis collimator lens 30.

FIG. 5 shows that the fast-axis collimator lens 30 is, by way of example, attached to the mounting plate 46 by means of an adhesive bond. The adhesive bond is created using a UV adhesive. UV adhesive is an adhesive that can be hardened by irradiation with ultraviolet light.

The fast-axis collimator lens 30 is positioned relative to the emitter 28 such that an emission direction 48, in which the laser emitter device 14 emits the laser beam 34, extends obliquely with respect to the longitudinal axis 32 of the emitter 28. In other words, by positioning the fast-axis collimator lens 30 relative to the emitter 28, the laser emitter device 14 is designed to emit the laser beam 34 in the emission direction 48 which is obliquely oriented to the longitudinal axis 32 of the emitter 28. Due to the oblique orientation of the emission direction 48, the emission direction 48 does not run parallel to the longitudinal axis 32 of the emitter 28.

The fast-axis collimator lens 30 can define a lens plane 50 and an optical plane 52. The lens plane 50 is the plane in which the fast-axis collimator lens 30 is positioned. A focal point of the fast-axis collimator lens 30 is spaced from the lens plane 50 by a focal length of the fast-axis collimator lens 30.

The optical plane 52 of the fast-axis collimator lens 30 is oriented perpendicular to the lens plane 50. The optical plane 52 of the fast-axis collimator lens 30 is a mirror symmetry plane of the fast-axis collimator lens 30. A laser beam passing through the fast-axis collimator lens 30 is refracted by the fast-axis collimator lens 30 in the direction of the optical plane 52.

The optical plane 52 intersects the lens plane 50 in a center axis 54 of the fast-axis collimator lens 30.

The fast-axis collimator lens 30 is positioned relative to the emitter 28 such that the longitudinal axis 32 of the emitter 28 and the optical plane 52 of the fast-axis collimator lens 30 have different courses for the purpose of emitting the laser beam 34 in the emission direction 28. In other words, the fast-axis collimator lens 30 is positioned such that the longitudinal axis 32 of the emitter 28 is not within the optical plane 52.

The fast-axis collimator lens 30 is positioned with a transverse offset 56 in the fast-axis direction 38 relative to the emitter 28. The transverse offset 56 is a distance between the longitudinal axis 32 of the emitter 28 and the center axis 54 of the fast-axis collimator lens 30. A distance between the longitudinal axis 32 of the emitter 28 and the flat surface portion 26 is smaller than a distance between the center axis 54 of the fast-axis collimator lens 30 and the flat surface portion 26.

Additionally, the fast-axis collimator lens 30 is tilted by a tilt angle 58 with respect to the longitudinal axis 32 of the emitter 28. The optical plane 52 of the fast-axis collimator lens 30 and the longitudinal axis 32 of the emitter 28 define the tilt angle 58 between them. In the illustrated exemplary embodiment, the tilt angle 58 is 3°.

Due to the transverse offset 56 and the tilt angle 58, the laser beam 34 generated by the emitter 28 is deflected away from the flat surface portion 26 by the fast-axis collimator lens 30 in the fast-axis direction 38. By means of the transverse offset 56 and the tilt angle 58 of the fast-axis collimator lens 30, the laser emitter device 14 is designed to emit the laser beam 34 in the emission direction 48 which is oriented obliquely relative to the flat surface portion 26.

The emission direction 48 and the flat surface portion 26 define a radiation angle 60 between them. In the illustrated exemplary embodiment, the radiation angle 60 is 4°.

The emission direction 48 is directed away from the flat surface portion 26. The emission direction 48 can be decomposed into a directional component parallel to the flat surface portion 26 and into a directional component perpendicular to the flat surface portion 26. The directional component perpendicular to the flat surface portion 26 is directed away from the flat surface portion 26.

The laser beam 34 leaves the laser emitter device 14 by exiting the fast-axis collimator lens 30. The laser beam 34 exits the laser emitter device 14 at an exit region of the fast-axis collimator lens 30. The exit region of the fast-axis collimator lens 30 forms a laser emitter output 62 of the laser emitter device 14.

The propagation direction 36 of the laser beam 34 after exiting the laser emitter device 14 is the same as the emission direction 48 in which the laser emitter device 14 emits the laser beam 34. In other words, after the laser beam exits the laser emitter device 14, the laser beam 34 propagates along its propagation direction 36, which extends obliquely with respect to the flat surface portion 26.

Due to the oblique emission of the laser beam 34 in the emission direction 48 from the laser emitter device 14, a distance 64 between the laser beam 34 and the flat surface portion 26 depends on a propagation path of the laser beam 34. A propagation path can be understood as the distance that the laser beam travels through propagation in the propagation direction.

The distance 64 is determined in a direction parallel to a perpendicular on the flat surface portion 26 from the flat surface portion 26 to the laser beam 34. The distance 64 can also be understood as a height at which the laser beam 34 is spaced from the flat surface portion 26. Since the laser beam 34 is emitted away from the flat surface portion 26 by the laser emitter device 14, the distance 64 increases with an increasing propagation path of the laser beam 34 from the laser emitter device 14.

FIG. 1 shows that the laser emitter devices 14 are positioned on the flat surface portion 26 such that the slow-axis directions 40 of the laser beams 34 are oriented parallel to the flat surface portion 26. The emission directions 48 are oriented parallel to one another. The propagation directions 36 are oriented parallel to one another. The longitudinal axes 32 of the emitters 28 are oriented parallel to one another.

Each laser emitter output 62 of the laser emitter devices 14, from which the laser beam 34 exits, is spaced at a distance from the flat surface portion 26. The distances of the laser emitter outputs 62 of the laser emitter device 14 from the flat surface portion 26 are equal in magnitude.

The laser emitter devices 14 are positioned on the flat surface portion 26 such that the laser emitter outputs 62 are positioned along a straight line. The straight line of the laser emitter outputs 62 is oriented parallel to the flat surface portion 26.

The laser emitter devices 14 are positioned on the flat surface portion 26 to form a laser emitter row 66. One direction 68 of the laser emitter row 66 runs parallel to the flat surface portion 26. Two adjacent laser emitter devices 14 are positioned at a distance 70 from each other on the flat surface portion 26. The distances 70 between the laser emitter devices 14 are equal.

In the propagation direction 36 after the laser emitter devices 14, a plurality of slow-axis collimator lenses 72 of the laser emitter assembly 10 are positioned on the flat surface portion 26. The slow-axis collimator lenses 72 are identically designed. In total, the laser emitter assembly 10 has 11 slow-axis collimator lenses 72. The number of slow-axis collimator lenses 11 corresponds to the number of laser emitter devices 14. Therefore, if fewer or more laser emitter devices 14 are present in exemplary embodiments not specifically shown, the number of slow-axis collimator lenses 11 is also changed accordingly.

Accordingly, each slow-axis collimator lens 72 is assigned to a laser emitter device 14 of the laser emitter assembly 10. This means that the number of slow-axis collimator lenses 72 is equal to the number of laser emitter devices 14.

Each slow-axis collimator lens 72 is set up to collimate the laser beam 34 in the slow-axis direction 40. In other words, every laser beam 34 that passes through the slow-axis collimator lens 72 is collimated in the slow-axis direction 40.

Each slow-axis collimator lens 72 is an aspherical cylindrical lens made of quartz glass. The slow-axis collimator lens 72 has an anti-reflective coating for a wavelength of the laser beam 34, i.e., to reduce a proportion of reflected light of the laser beam 34 at the slow-axis collimator lens 72 to a relative minimum.

Each slow-axis collimator lens 72 is attached to the base 16, for example, by means of an adhesive bond as shown here. The adhesive bond is created using a UV adhesive.

The slow-axis collimator lenses 72 are positioned on the flat surface portion 26 to form a slow-axis collimator lens row 74. One direction 76 of the slow-axis collimator lens row 74 runs parallel to the flat surface portion 26. The direction 76 of the slow-axis collimator lens row 74 runs parallel to the direction 68 of the laser emitter row 66.

In the propagation direction 36 after the slow-axis collimator lenses 72, a plurality of deflecting mirrors 78 of the laser emitter assembly 10 are positioned on the flat surface portion 26. The deflecting mirrors 78 are identical in design. In total, the laser emitter assembly 10 has 11 deflecting mirrors 78.

Each deflecting mirror 78 is assigned to a laser emitter device 14 of the laser emitter assembly 10. This means that the number of deflecting mirrors 78 is equal to the number of laser emitter devices 14.

Each deflecting mirror 78 is attached to the base 16 by means of an adhesive bond. The adhesive bond is created using a UV adhesive.

Each deflecting mirror 78 is designed to deflect the propagation direction 36 of the laser beam 34 of the laser emitter device 14 associated with the deflecting mirror 78 by 90°. In other words, each laser beam 34 strikes the deflecting mirror 78 at an angle of incidence of 45°. Deflecting the laser beam 34 by means of the deflecting mirror 78 is a change in the propagation direction 36 of the laser beam 34.

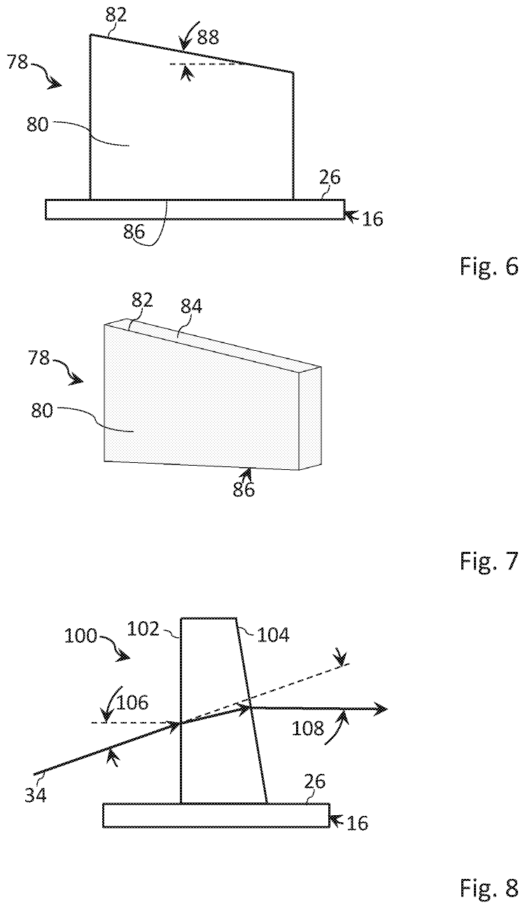

FIG. 6 shows a deflecting mirror 78 of the laser emitter assembly 10 and the base 16. FIG. 7 shows the deflecting mirror 78 of FIG. 6 without the base 16.

The deflecting mirror 78 has a mirror surface 80. The mirror surface 80 is oriented perpendicular to the flat surface portion 26.

The mirror surface 80 is designed to deflect the propagation direction 36 of the laser beam 34 of the laser emitter device 14 associated with the deflecting mirror 78. In particular, the mirror surface 80 is designed to reflect the laser beam 34 of the laser emitter device 14 associated with the deflecting mirror 78.

The mirror surface 80 is formed from alternating, thin layers of different refractive indices. In other words, the deflecting mirror 78 is a Bragg mirror.

The deflecting mirror 78 has a straight edge 82 that extends obliquely with respect to the flat surface portion 26. In other words, the straight edge 82 is oriented obliquely to the flat surface portion 26. The obliquely oriented straight edge 82 is designed without curvature and extends along a straight line.

The obliquely oriented straight edge 82 forms a corner of the deflecting mirror 78. The obliquely oriented straight edge 82 delimits the mirror surface 80. The obliquely oriented straight edge 82 delimits a side surface 84 of the deflecting mirror 78, which is facing away from the flat surface portion 26. The side surface 84 is oriented perpendicular to the mirror surface 80. The obliquely oriented straight edge 82 is a boundary between the mirror surface 80 and the side surface 84 facing away from the flat surface portion 26. In other words, the obliquely oriented straight edge 82 is positioned between the mirror surface 80 and the side surface 84 facing away from the flat surface portion 26.

The deflecting mirror 78 has a further side surface 86. The further side surface 86 is positioned opposite to the side surface 84. The further side surface 86 faces towards the flat surface portion 26. The side surface 84 and the further side surface 86 are oriented in opposite directions to one another.

The obliquely extending course of the straight edge 82 and the flat surface portion 26 define an angle 88 between them. The angle 88 between the obliquely extending straight edge 82 and the flat surface portion 26 satisfies the condition

$${α}^{′} = atan ( \frac{tan α}{\sqrt{2}} ) ,$$

wherein α is the radiation angle 60 and α′ is the angle 88.

FIG. 1 shows that the deflecting mirrors 78 are positioned on the flat surface portion 26, forming a deflecting mirror row 90. One direction 92 of the deflecting mirror row 90 runs parallel to the flat surface portion 26. The direction 92 of the deflecting mirror row 90 runs parallel to the direction 68 of the laser emitter row 66. The direction 92 of the deflecting mirror row 90 runs parallel to the direction 76 of the slow-axis collimator lens row 74.

Each deflecting mirror 78, except for the deflecting mirror 78 positioned closest to the output 12, deflects the respective laser beam 34 such that the deflected laser beam 34 passes by the straight edge 82 of another deflecting mirror 78 extending obliquely. The further deflecting mirror 78 is positioned between the laser beam 34 deflected by the deflecting mirror 78 and the flat surface portion 26.

The oblique emission of the laser beams 34 enables the use of identically designed deflecting mirrors 78. The deflecting mirrors 78 are spaced apart from each other in the direction 92 of the deflecting mirror row 90 such that the distances 64 between the laser beams 34 and the flat surface portion 26 increase for a propagation path equal to the distance between two adjacent deflecting mirrors 78 such that the laser beams 34 are guided past the deflecting mirrors 78 without striking them.

Each deflecting mirror 78 is spaced at a distance 94 from the laser emitter device 14 associated with the deflecting mirror 78. The distances 94 between each deflecting mirror 78 and the laser emitter device 14 associated with the deflecting mirror 78 are equal.

Each deflecting mirror 78 is spaced at a distance 96 from the output 12. The distances 96 differ from each other. As a result, each laser beam 34 travels a propagation path of varying length from the laser emitter device 14 to the output 12. As a result, the distances 64 between the laser beams 34 and the flat surface portion 26 at the output 12 differ from each other.

The propagation directions 36 of the laser beams 34 are oriented parallel to one another after deflection by means of the deflecting mirrors 78. The laser beams 34 are positioned one above the other in the fast-axis direction 38 after being deflected by means of the deflecting mirrors 78. The deflecting mirrors 78 are designed to arrange the laser beams 34 one above the other such that the laser beams 34 are spaced at an equal distance from each other.

The output laser beam 98 is formed by arranging the individual laser beams 34 relative to one another by means of the deflecting mirrors 78. The output laser beam 98 is a laser beam group formed from the laser beams 34. The formation of the output laser beam 98 is an assembly of the laser beams 34 in the fast-axis direction 38 one above the other by means of the deflecting mirrors 78.

The output laser beam 98 propagates in a propagation direction. In other words, the formed laser beam group propagates in a propagation direction which results from the individual propagation directions 36 of the laser beams 34. Since the propagation directions 36 of the laser beams 34 are oriented parallel to one another after deflection by means of the deflecting mirrors, the propagation direction of the output laser beam 98 is oriented parallel to all propagation directions 36 of the laser beams 34.

An optical device 100 of the laser emitter assembly 10 is positioned on the flat surface portion 26 in the propagation direction 36 after the deflecting mirrors 78. The optical device 100 is positioned in a beam path of the laser beams 34 between the output 12 and the deflecting mirrors 78.

The optical device 100 is designed as a one-piece optical component of the laser emitter assembly 10. The optical device 100 is designed as an independent optical component of the laser emitter assembly 10. In other words, the optical device 100 is designed separately from the other optical components of the laser emitter assembly 10.

The optical device 100 is attached to the base 16 by means of an adhesive bond. The adhesive bond is created using a UV adhesive.

The laser beams 34 pass through the optical device 100 for the purpose of changing the propagation directions 36. The optical device 100 is transparent to a wavelength of the laser beams 34.

FIG. 8 shows the optical device 100 of the laser emitter assembly 10 and the base 16. The optical device 100 is designed as an optical wedge made of quartz glass.

The optical device 100 has a flat entry surface 102 and a flat exit surface 104. The flat entry surface 102 and the flat exit surface 104 extend obliquely relative to one another.

The laser beams 34 strike the flat entry surface 102 of the optical device 100, pass through the optical device 100 and exit from the flat exit surface 104 out of the optical device 100.

Each laser beam 34 strikes the flat entry surface 102 at an angle of incidence 106. The angle of incidence 106 is defined by a perpendicular on the flat entry surface 102 and the propagation direction 36 of the laser beam 34. All angles of incidence 106 are the same.

The flat entry surface 102 and the flat exit surface 104 each form a phase boundary for the laser beams 34. The optical device 100 is designed to change each propagation direction 36 of the laser beams 34 in the fast-axis direction by means of refraction at the flat entry surface 102 and at the flat exit surface 104. In other words, the optical device 100 is designed to change the propagation directions 36 of the laser beams 34 in the direction of the flat surface portion 26 by means of refraction at the flat entry surface 102 and at the flat exit surface 104. This deflects the laser beams 34 by means of the optical device 100 in the direction of the flat surface portion 26.

The optical device 100 is designed to change each propagation direction 36 of the laser beams 34 by a deflection angle 108. Each deflection angle 108 is defined between the propagation direction 36 of the laser beam 34 before passing through the optical device 100 and the propagation direction 36 of the laser beam 34 after passing through the optical device 100. Each deflection angle 108 of the laser beams 34 and the radiation angle 60 of the laser beams 34 are the same.

After passing through the optical device 100, the propagation direction of the output laser beam 98 is oriented parallel to the flat surface portion 26. Each laser beam 34 propagates parallel to the flat surface portion 26 after passing through the optical device 100. In other words, after passing through the optical device 100, the propagation directions 36 of the laser beams 34 are oriented parallel to the flat surface portion 26. This allows the optical device 100 to compensate for the obliquely extending emission directions 48.

In the propagation direction 36 after the optical device 100, every distance 64 between the laser beam 34 and the flat surface portion 26 is constant. In other words, once a laser beam 34 has passed through the optical device 100, the distance 64 between the laser beam 34 and the flat surface portion 26 no longer changes depending on the propagation path of the laser beam 34.

In the propagation direction 36 after the optical device 100, a focusing device 110 of the laser emitter assembly 10 is positioned on the flat surface portion 26. The focusing device 110 is attached to the base 16 by means of an adhesive bond. The adhesive bond is created using a UV adhesive.

The focusing device 110 is designed to focus the output laser beam 98 onto the output 12. The focusing device 110 is designed as a focusing lens made of quartz glass. The focusing device 110 has an anti-reflective coating for a wavelength of the laser beams 34 of the laser emitter devices 14. The anti-reflective coating reduces the reflectance of the laser beam 34 at the interfaces of the focusing device 110.

The focusing device 110 is positioned on the flat surface portion 26 such that the output 12 lies in a focal plane of the focusing device 110 in the propagation direction of the output laser beam 98 following the focusing device 110.

The focusing device 110 focuses the output laser beam 98 onto the output 12 such that the output laser beam 98 has a predetermined beam diameter and a predetermined divergence at the output 12. In other words, the output laser beam 98 exits the output with the predetermined beam diameter and the predetermined divergence. In the exemplary example shown, the predetermined beam diameter is 400 μm and the predetermined divergence is 40°.

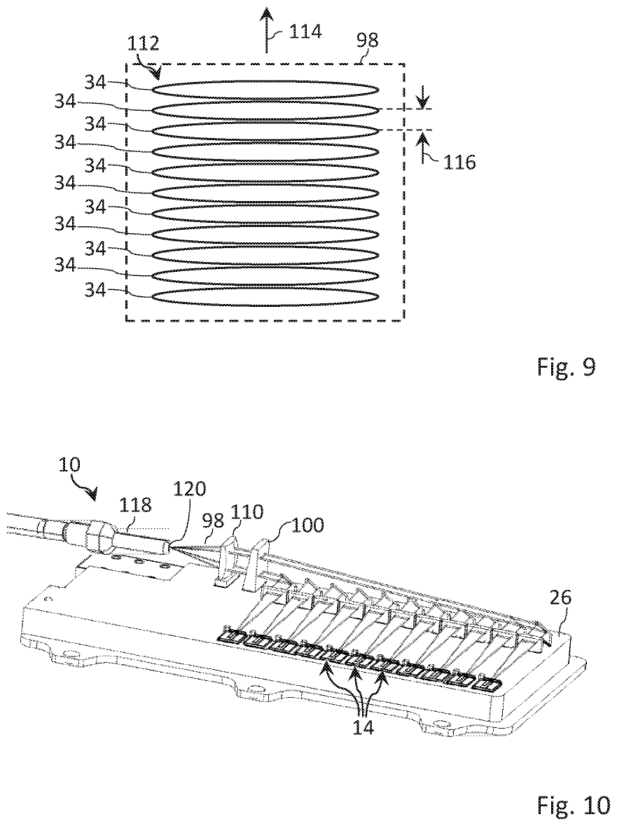

FIG. 9 schematically shows a cross-section of the output laser beam 98 at the output 12. A beam profile of the output laser beam 98 is formed by the laser beams 34 positioned one above the other in the fast-axis direction 38. The laser beams 34 are positioned relative to one another in the cross-section to form a laser beam row 112. One direction 114 of the laser beam row 112 is oriented perpendicular to the flat surface portion 26.

The laser beams 34 are positioned one above the other at an equal distance 116 in the fast-axis direction 38. Each distance 116 between two adjacent laser beams 43 depends on the propagation paths of the two adjacent laser beams 43 from the laser emitter devices 14 emitting the two adjacent laser beams 43 to the optical device 100.

For example, the distance 116 between the two adjacent laser beams 43 changes when the propagation path of one of the two adjacent laser beams 43 between the laser emitter device 14 emitting the laser beam 43 and the optical device 100 is lengthened or shortened. The dependence of the output laser beam 98 on the propagation paths is achieved by the propagation directions 36 of the laser beams 34 extending obliquely relative to the flat surface portion 26.

Thus, the positions of the laser beams 34 in the cross-section of the output laser beam 98 are determined by the propagation paths from the laser emitter devices 14 to the output 12. In other words, the output laser beam 98 is formed depending on the propagation paths from the laser emitter devices 14 to the output 12. The dependence on the propagation paths refers to a dependence on the lengths of the propagation paths.

The lengths of the propagation paths of the laser beams 34 depend on an assembly of the laser emitter devices 14 on the flat surface portion 26. This means that the output laser beam 98 is formed from the laser beams 34 depending on the positions of the laser emitter devices 14 on the flat surface portion 26.

In the illustrated exemplary embodiment, the laser emitter assembly 10 has a housing (not shown). The base 16 forms a side wall of the housing. The housing has an interior, in which the laser emitter devices 14, the slow-axis collimator lenses 72, the deflecting mirrors 78, the optical device 100 and the focusing device 110 are positioned. The output 12 is formed by an opening in the housing. The output laser beam 98 is focused on the opening by means of the focusing device 110. The output laser beam 98 passes through the opening and exits the housing.

FIG. 10 shows a further exemplary embodiment of a laser emitter assembly 10, wherein the same reference signs are used for identical and functionally equivalent elements and, in this respect, reference can be made to the explanations given above in relation to the exemplary embodiment of FIGS. 1 to 9, with the result that essentially only the existing differences are discussed.

The laser emitter assembly 10 of FIG. 10 has a waveguide receptacle (not shown) for receiving a waveguide 118 in the form of an optical fiber cable for guiding the output laser beam 98. The receptacle is positioned at an opening in the housing of the laser emitter assembly 10. The waveguide 118 is accommodated in the receptacle. The waveguide 118 is accommodated by the receptacle, such that an end face 120 of the waveguide 118 is positioned at the output 12. The output laser beam 98 is focused onto the output 12 by means of the focusing device 110 such that the output laser beam 98 is coupled into the waveguide 118. The output laser beam 98 is thus designed to be coupled into the waveguide 118, if the end face 120 of the waveguide 118 is positioned, in particular placed, at the output 12.

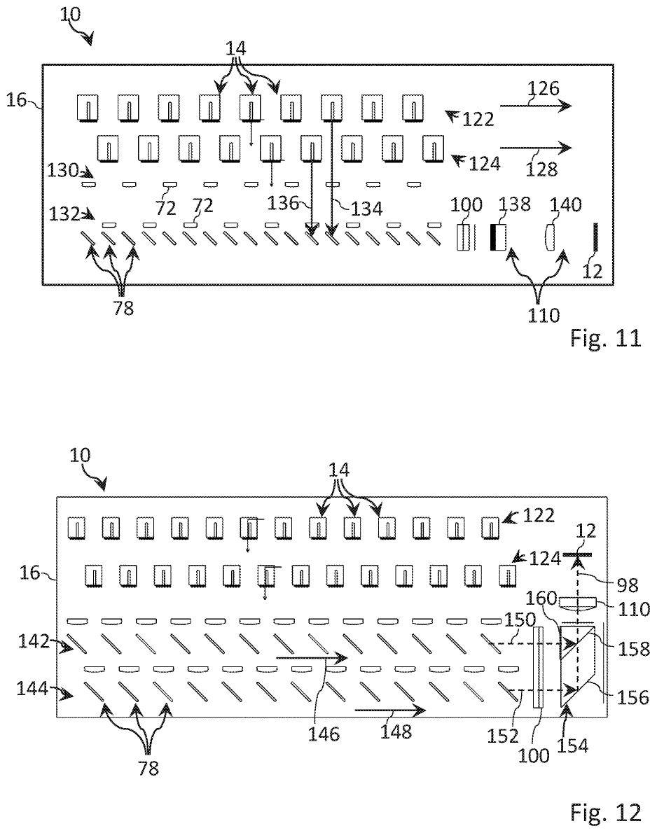

FIG. 11 shows a further exemplary embodiment of a laser emitter assembly 10, wherein the same reference signs are used for identical and functionally equivalent elements and, in this respect, reference can be made to the explanations given above in relation to the exemplary embodiments of FIGS. 1 to 10, with the result that essentially only the existing differences are discussed.

The laser emitter devices 14 are positioned on the flat surface portion 26 of the base 16 to form a first laser emitter row 122 and a second laser emitter row 124. Each laser emitter row 122, 124 is formed from 9 laser emitter devices 14.

The first laser emitter row 122 extends in a direction 126. The direction 126 of the first laser emitter row 122 runs parallel to the flat surface portion 26. The second laser emitter row 124 extends in a direction 128. The direction 128 of the second laser emitter row 124 runs parallel to the flat surface portion 26. The direction 126 of the first laser emitter row 122 is oriented parallel to the direction 128 of the second laser emitter row 124.

The first laser emitter row 122 and the second laser emitter row 124 are oriented offset to one another. The first laser emitter row 122 and the second laser emitter row 124 are oriented offset to one another such that, between two adjacent laser emitter devices of the second laser emitter row 124, a laser beam 34 of a laser emitter device 14 of the first laser emitter row 122 is guided past the two adjacent laser emitter devices 14 of the second laser emitter row 124. This means that the laser beams 34 in the cross-section of the output laser beam 98 at the output 12 are positioned relative to one another such that, between two adjacent laser beams 34 of the laser emitter device 14 of the first laser emitter row 122, a laser beam 34 of the laser emitter device 14 of the second laser emitter row 124 is positioned.

The slow-axis collimator lenses 72 are positioned on the flat surface portion 26 to form a first slow-axis collimator lens row 130 and a second slow-axis collimator lens row 132. The slow-axis collimator lenses 72 of the first slow-axis collimator lens row 130 are assigned to the laser emitter devices 14 of the first laser emitter row 122. The slow-axis collimator lenses 72 of the second slow-axis collimator lens row 132 are assigned to the laser emitter devices 14 of the second laser emitter row 124.

Each laser emitter device 14 of the first laser emitter row 122 is spaced at a distance 134 from the deflecting mirror 78 associated with the laser emitter device 14. Each laser emitter device 14 of the second laser emitter row 124 is spaced at a distance 136 from the deflecting mirror 78 associated with the laser emitter device 14.

The distance 134 between the laser emitter devices 14 of the first laser emitter row 122 and the deflecting mirrors 78 is greater than the distance 136 between the laser emitter devices 14 of the second laser emitter row 124 and the deflecting mirrors 78.

The radiation angles 60 between the emission directions 48 of the laser emitter devices 14 of the first laser emitter row 122 and the flat surface portion 26 are smaller in their magnitudes than the magnitudes of the radiation angles 60 between the emission directions 48 of the laser emitter devices 14 of the second laser emitter row 124 and the flat surface portion 26.

The deflecting mirrors 78 assigned to the laser emitter devices 14 of the second laser emitter row 122 are each oriented orthogonally to the flat surface portion 26.

The deflecting mirrors 78 assigned to the laser emitter devices 14 of the first laser emitter row 122 are each oriented at a tilt angle to the flat surface portion 26. In the exemplary embodiment shown, the deflecting mirrors 78 assigned to the laser emitter devices 14 of the first laser emitter row 122 are each oriented at a tilt angle to the flat surface portion 26 such that the laser beams 34 of the laser emitter devices 14 of the first laser emitter row 122 and the laser beams 34 of the laser emitter devices 14 of the second laser emitter row 124 are oriented parallel to one another after being deflected by the deflecting mirrors 78.

In the exemplary embodiment of FIG. 11, the focusing device 110 has a first cylindrical lens 138 and a second cylindrical lens 140. The first cylindrical lens 138 and the second cylindrical lens 140 are set up to focus the output laser beam 98 onto the output 12.

The first cylindrical lens 138 and the second cylindrical lens 140 are each an aspherical cylindrical lens made of quartz glass with a comparatively high refractive index. The first cylindrical lens 138 and the second cylindrical lens 140 each have an anti-reflective coating for a wavelength of the laser beams 34. In exemplary embodiments not specifically shown, the cylindrical lenses 140 are spherically shaped.

The first cylindrical lens 138 is designed to focus the output laser beam 98 in the fast-axis direction 38 onto the output 12. The second cylindrical lens 140 is designed to focus the output laser beam 98 in the slow-axis direction 40 onto the output 12.

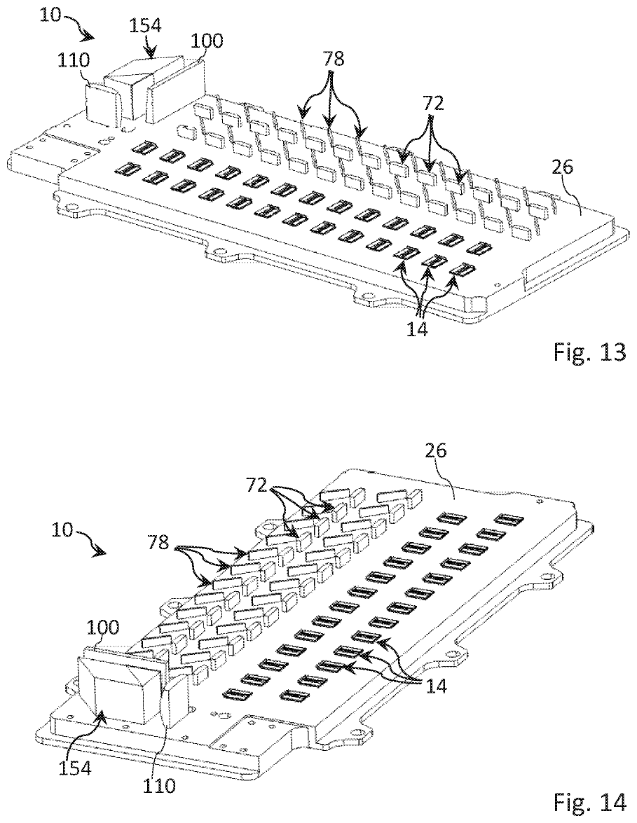

FIGS. 12 to 14 show a further exemplary embodiment of a laser emitter assembly 10, wherein the same reference signs are used for identical and functionally equivalent elements and, in this respect, reference can be made to the explanations given above in relation to the exemplary embodiments of FIGS. 1 to 11, with the result that essentially only the existing differences are discussed.

Each laser emitter row 122, 124 is formed from 13 laser emitter devices 14.

The deflecting mirrors 78 are positioned on the flat surface portion 26 to form a first deflecting mirror row 142 and a second deflecting mirror row 144.

The first deflecting mirror row 142 extends in a direction 146. The direction 146 of the first deflecting mirror row 142 runs parallel to the flat surface portion 26. The second deflecting mirror row 144 extends in a direction 148. The direction 148 of the second deflecting mirror row 144 runs parallel to the flat surface portion 26. The direction 146 of the first deflecting mirror row 142 is oriented parallel to the direction 148 of the second deflecting mirror row 144.

The first deflecting mirror row 142 is assigned to the laser emitter device 14 of the first laser emitter row 122. The second deflecting mirror row 144 is assigned to the laser emitter devices 14 of the second laser emitter row 124.

The first deflecting mirror row 142 and the second deflecting mirror row 144 are positioned offset to one another on the flat surface portion 26. The first deflecting mirror row 142 and the second deflecting mirror row 144 are positioned offset from each other such that a laser beam 34 of a laser emitter device 14 of the second laser emitter row 124 is guided between two adjacent deflection mirrors 78 of the first deflecting mirror row 142.

By means of the first deflecting mirror row 142, the laser beams 34 of the laser emitter devices 14 of the first laser emitter row 122 are positioned one above the other in the fast-axis direction 38. The laser beams 34 of the laser emitter devices 14 of the first laser emitter row 122 positioned one above the other in the fast-axis direction 38 form a first laser beam group 150. The first laser beam group 150 is represented in FIG. 12 by a dashed arrow.

By means of the second deflecting mirror row 144, the laser beams 34 of the laser emitter devices 14 of the second laser emitter row 124 are positioned one above the other in the fast-axis direction 38. The laser beams 34 of the laser emitter devices 14 of the second laser emitter row 124 positioned one above the other in the fast-axis direction 38 form a second laser beam group 152. The second laser beam group 152 is represented in FIG. 12 by a dashed arrow.

The two laser beam groups 150, 152 propagate parallel and offset relative to one another. The two laser beam groups 150, 152 pass through the optical device 100 at different points.

The laser emitter assembly 10 has a polarization coupling device 154. The output laser beam 98 is formed by polarization coupling of the two laser beam groups 150, 152. The output laser beam 98 is represented in FIG. 12 by a dashed arrow.

The polarization coupling device 154 has a mirror 156, a polarizer 158 and a retardation plate in the form of a λ/2 plate 160. The polarization coupling device 154 is designed as one, in particular single, component.

The laser beams 34 are linearly polarized. The linear polarizations of the laser beams 34 are oriented parallel to one another before passing through the polarization coupling device 154. In other words, before passing through the polarization coupling device 154, the polarization of all laser beams 34 is oriented in the same direction.

The λ/2 plate 160 is positioned such that the laser beams 34 of the first laser beam group 150 pass through the λ/2 plate. The λ/2 plate 160 is designed to rotate the polarization of the laser beams 34 of the first laser beam group 150 by 90°. This means that the polarization of the laser beams 34 of the first laser beam group 150 is oriented orthogonally to the polarization of the second laser beam group 152.

After passing through the λ/2 plate, the laser beams 34 of the first laser beam group 150 strike the polarizer 158. The polarizer 158 is designed to reflect or transmit the laser beams 34 depending on their polarization. In the exemplary embodiment shown in FIG. 12, the polarizer 158 reflects the laser beams 34 of the first laser beam group 150 due to the orientation of their polarization.

The second laser beam group 152 strikes the mirror 156 as it passes through the polarization coupling device 154. The second laser beam group 152 is deflected by 90° by the mirror 156. By deflecting the second laser beam group 152 by means of the mirror 156, the second laser beam group 152 is directed towards the polarizer 158. In the exemplary embodiment shown in FIG. 12, the polarizer 158 transmitted the laser beams 34 of the second laser beam group 152 due to the orientation of their polarization.

The polarizer 158 spatially superimposes the laser beams 34 of the first laser beam group 150 with the laser beams 34 of the second laser beam group 152 to form the output laser beam 98. In other words, the output laser beam 98 is formed by means of the polarizer 158 by spatially superimposing the laser beams 34 of the first laser beam group 150 with the laser beams 34 of the second laser beam group 152.

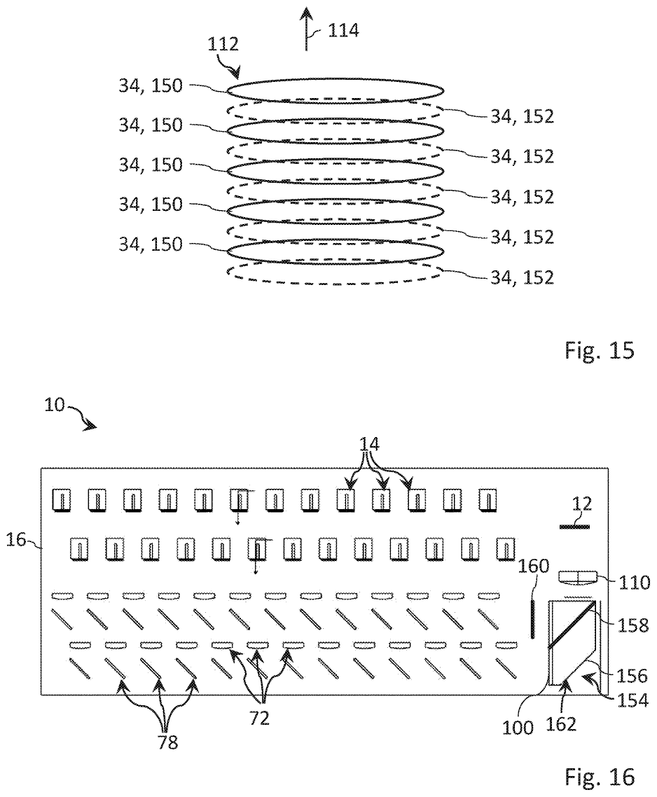

FIG. 15 schematically illustrates a portion of a cross-section of the output laser beam 98 at the output 12, wherein, for reasons of clarity, not all laser beams 34 from the laser emitter devices 14 are shown in FIG. 15. The laser beams 34 of the second laser beam group 152 are shown as dashed lines in FIG. 15.

The output laser beam 98 is formed by polarization coupling using the polarization coupling device 154 such that a laser beam 34 of the second laser beam group 152 is positioned at the output between two adjacent laser beams 34 of the first laser beam group 150. The laser beams 34 of the first laser beam group 150 and the laser beams 34 of the second laser beam group 152 are partially superimposed. However, an exemplary embodiment, in which the laser beams 34 are not superimposed, is also conceivable.

In an alternative exemplary embodiment that is not shown, the output laser beam is formed by spatially superimposing the laser beams of the first laser beam group with the laser beams of the second laser beam group by wavelength coupling using a wavelength coupling device of the laser emitter assembly.

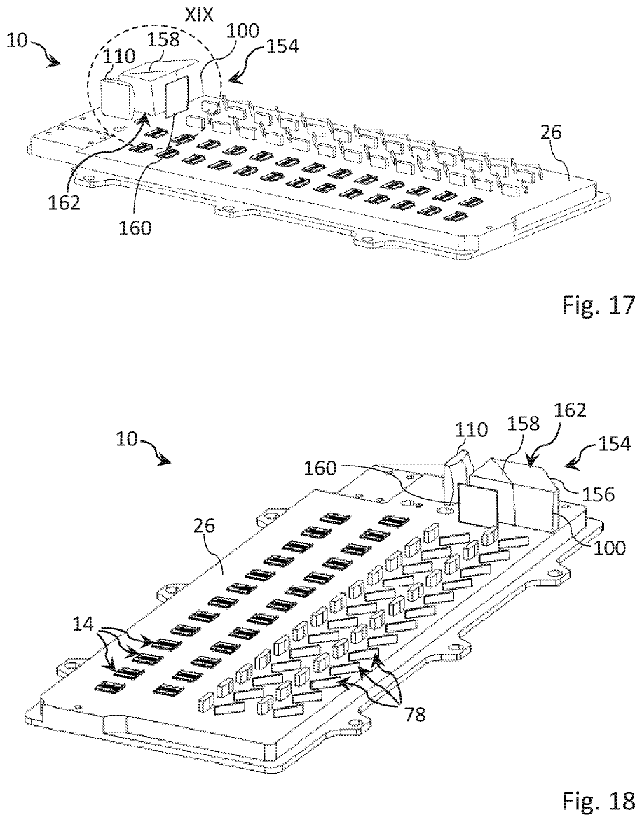

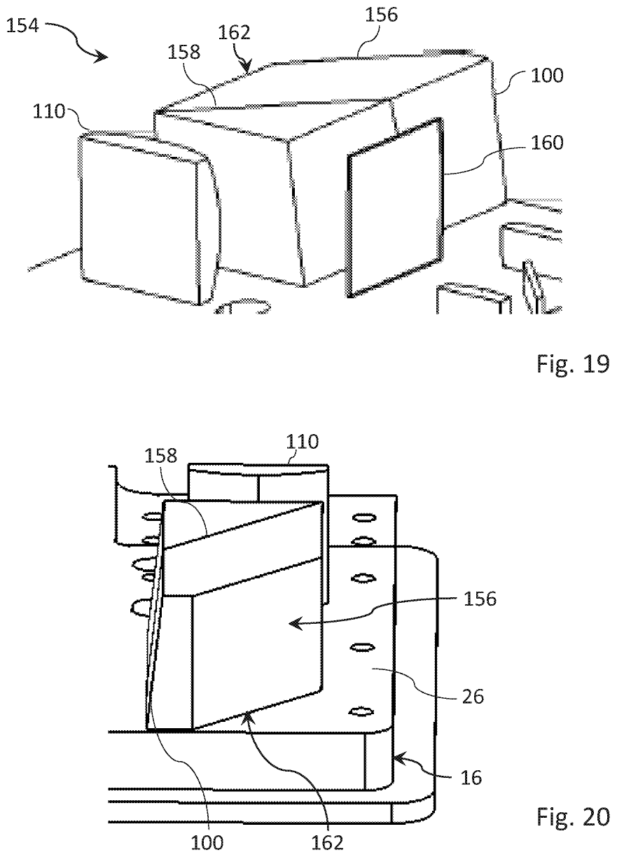

FIGS. 16 to 21 show a further exemplary embodiment of a laser emitter assembly 10, wherein the same reference signs are used for identical and functionally equivalent elements and, in this respect, reference can be made to the explanations given above in relation to the exemplary embodiments of FIGS. 1 to 15, with the result that essentially only the existing differences are discussed.

The optical device 100 is materially bonded to the polarizer 158 of the polarization coupling device 154 and the mirror 156 of the polarization coupling device 154 to form a coupling element 162 of the laser emitter assembly 10. In other words, the coupling element 162 is designed as a single component. The coupling element 162 is made of quartz glass.

The λ/2 plate 160 of the polarization coupling device 154 is designed separately from the coupling element 162.

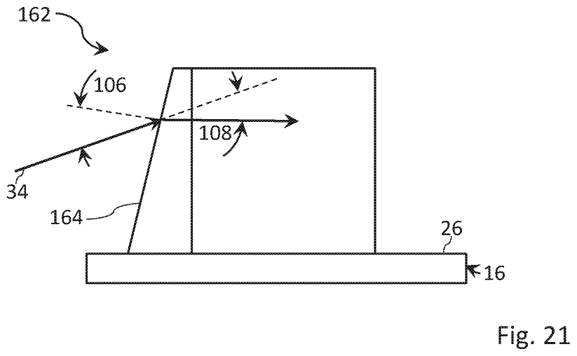

FIG. 21 shows the coupling element 162 of the laser emitter assembly 10 and the base 16.

The optical device 100 is formed by a flat entry surface 164 of the coupling element 162. The flat entry surface 164 is oriented obliquely to the flat surface portion 26. Each laser beam 34 strikes the flat entry surface 164 at the angle of incidence 106.

The flat entry surface 164 forms a phase boundary for the laser beams 34. Each propagation direction 36 of the laser beams 34 is changed by means of refraction at the flat entry surface 164 onto the flat surface portion 26. This changes the propagation directions 36 of the laser beams 34 by the deflection angle 108.

After passing the flat entry surface 164, the propagation directions 36 of the laser beams 34 are oriented parallel to the flat surface portion 26.

A method according to embodiments of the invention is configured to operate a previously described laser emitter assembly.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A laser emitter assembly for providing an output laser beam at an output of the laser emitter assembly, the laser emitter assembly comprising:
a base, and
a plurality of laser emitter devices attached to the base, each laser emitter device comprising an emitter,
wherein each respective laser emitter device is configured to generate a respective laser beam and emit the respective laser beam in a respective emission direction,
wherein each respective emission direction extends obliquely with respect to the base and/or with respect to a longitudinal axis of the emitter of the respective laser emitter device, and
wherein the output laser beam is formed from the laser beams of the plurality of laser emitter devices.

2. The laser emitter assembly according to claim 1,
wherein the base has a flat surface portion,
wherein the plurality of laser emitter devices is positioned on the flat surface portion, and
wherein each respective emission direction extends obliquely relative to the flat surface portion.

3. The laser emitter assembly according to claim 1,
wherein each respective emission direction and the base define a radiation angle therebetween that is not equal to 0°, and/or
wherein each respective emission direction and the longitudinal axis of the emitter define a radiation angle therebetween that is not equal to 0°.

4. The laser emitter assembly according to claim 3,
wherein the radiation angle between the respective emission direction and the base and/or the radiation angle between the respective emission direction and the longitudinal axis of the emitter is in a range between 0.5° to 20°.

5. The laser emitter assembly according to claim 1,
wherein each respective laser emitter device comprises a fast-axis collimator lens for collimating the respective laser beam in a fast-axis direction, and
wherein the fast-axis collimator lens of each respective laser emitter device is positioned relative to the emitter such that the respective emission direction extends obliquely with respect to the base and/or with respect to the longitudinal axis of the emitter.

6. The laser emitter assembly according to claim 5,
wherein the longitudinal axis of the emitter of each respective laser emitter device and an optical plane of the fast-axis collimator lens have different orientations.

7. The laser emitter assembly according to claim 5,
wherein the fast-axis collimator lens of each respective laser emitter device is arranged with a transverse offset in the fast-axis direction relative to the emitter.

8. The laser emitter assembly according to claim 5,
wherein the fast-axis collimator lens of each respective laser emitter device is tilted by a tilt angle with respect to the longitudinal axis of the emitter.

9. The laser emitter assembly according to claim 8,
wherein the tilt angle is in a range from 0.5° to 20°.

10. The laser emitter assembly according to claim 1,
wherein the longitudinal axis of the emitter extends obliquely with respect to the base.

11. The laser emitter assembly according to claim 1,
further comprising a housing,
wherein the base forms a wall section of the housing.

12. The laser emitter assembly according to claim 1,
wherein each respective laser beam travels along a propagation path from the respective laser emitter device to the output of the laser emitter assembly, and
wherein the output laser beam is formed from the laser beams of the plurality of laser emitter devices depending on the propagation paths from the plurality of laser emitter devices to the output.

13. The laser emitter assembly according to claim 1,
further comprising an optical device positioned between the output and the plurality of laser emitter devices,
wherein the laser beams pass through the optical device for changing propagation directions of the laser beams.

14. A method for providing an output laser beam at an output of a laser emitter assembly, the method comprising:
attaching a plurality of laser emitter devices of the laser emitter assembly to a base of the laser emitter assembly, wherein each respective laser emitter device comprises an emitter,
generating laser beams by using the plurality of laser emitter devices and emitting the laser beams from the plurality of laser emitter devices, each respective laser beam is emitted in a respective emission direction extending obliquely with respect to the base and/or with respect to a longitudinal axis of the emitter, and
forming the output laser beam from the laser beams of the plurality of laser emitter devices.
